(19) United States
(12) Patent Application Publication
(10) Pub. No.: US 2026/0162741 A1
(43) Pub. Date: Jun. 11, 2026

(54) MEMORY DEVICE AND METHOD FOR PERFORMING PROGRAM OPERATION THEREOF

(71) Applicant: SK hynix Inc., Gyeonggi-do (KR)

(72) Inventor: Duck Ju KIM, Gyeonggi-do (KR)

(21) Appl. No.: 19/248,470

(22) Filed: Jun. 25, 2025

(30) Foreign Application Priority Data
Dec. 10, 2024 (KR) 10-2024-0182863

(51) Int. Cl. G11C 16/34; G11C 16/08; G11C 16/10

(52) U.S. Cl. CPC G11C 16/3459; G11C 16/08; G11C 16/102

(57) ABSTRACT

A memory device includes a memory cell array including memory cells coupled to a selected word line, a peripheral circuit performing a program operation on the memory cells by applying program voltages to the selected word line, and a control logic grouping program pulses to be applied to the memory cells into groups according to an order of target threshold voltages of the memory cells, and controlling the peripheral circuit so that the program pulses included in the groups are applied to the memory cells in descending order of representative threshold voltages of the groups, wherein a representative threshold voltage of each of the groups is the lowest target threshold voltage among the target threshold voltages of the program pulses included in each of the groups.

### CROSS-REFERENCE TO RELATED APPLICATION

The present application claims priority under 35 U.S.C. § 119(a) to Korean patent application number 10-2024-0182863 filed on Dec. 10, 2024, the entire disclosure of which is incorporated herein by reference.

### BACKGROUND

### 1. Technical Field

Various embodiments of the present disclosure generally relate to a memory device, and more particularly, to a memory device and a method for grouping program pulses applied to memory cells to sequentially perform a program operation.

### 2. Related Art

Memory devices are divided into volatile memory devices and non-volatile memory devices. The volatile memory devices are memory devices that store data only when power is supplied, and the stored data disappears when the power supply is cut off. The non-volatile memory devices are memory devices in which data does not disappear even when power is cut off.

The memory devices may apply program pulses to the memory cells to perform program operations. As the number of threshold voltage distributions of the memory cells increases, there is a need to improve the threshold voltage distribution of the memory cells, so that the number of program pulses may increase. Due to an increase in the number of threshold voltage distributions of the memory cells and the number of program pulses, a program disturb may occur in which the threshold voltage distribution of the memory cells having a low target threshold voltage is widened.

### SUMMARY

Embodiments of the present disclosure may provide a memory device and a method for performing a program operation, in which a program pulse corresponding to a memory cell having a high target threshold voltage is applied before a program pulse corresponding to a memory cell having a low target threshold voltage during the program operation to improve performance of the program operation.

According to an embodiment of the present disclosure, a memory device may include a memory cell array including a plurality of memory cells coupled to a selected word line; a peripheral circuit for performing a program operation on the plurality of memory cells by applying program voltages to the selected word line; and a control logic for grouping a plurality of program pulses to be applied to the plurality of memory cells into a plurality of groups according to an order of target threshold voltages of the plurality of memory cells, and controlling the peripheral circuit so that the program pulses included in the plurality of groups are applied to the plurality of memory cells in descending order of representative threshold voltages of the plurality of groups, wherein a representative threshold voltage of each of the plurality of groups is the lowest target threshold voltage among the target threshold voltages of the program pulses included in each of the plurality of groups.

According to an embodiment of the present disclosure, a method of operating a memory device may include grouping a plurality of program pulses to be applied to a plurality of memory cells coupled to a selected word line into a plurality of groups according to an order of target threshold voltages of the plurality of memory cells; determining a representative threshold voltage of each of the plurality of groups to be a lowest target threshold voltage of the target threshold voltages of the plurality of memory cells corresponding to program pulses included in each of the plurality of memory cells; and applying program pulses corresponding to the representative threshold voltage included in each of the plurality of groups sequentially according to descending order of the representative threshold voltages of the plurality of groups.

### BRIEF DESCRIPTION OF THE DRAWINGS

FIG. 1 is a diagram illustrating a memory device according to an embodiment of the present disclosure;

FIG. 2 is a diagram illustrating program pulses applied to memory cells during a program operation;

FIG. 3 is a diagram illustrating a program pulse applying operation according to an embodiment of the present disclosure;

FIG. 4 is a diagram illustrating a threshold voltage distribution of memory cells programmed according to the program pulse applying operation of FIG. 3;

FIG. 5 is a diagram illustrating a program pulse applying operation and a threshold voltage distribution of memory cells according to another embodiment of the present disclosure;

FIG. 6 is a diagram illustrating a program pulse applying operation and a threshold voltage distribution of memory cells according to another embodiment of the present disclosure;

FIG. 7 is a flowchart illustrating a program operation according to an embodiment of the present disclosure; and

FIG. 8 is a diagram exemplarily illustrating a data storage system including a memory system according to an embodiment of the present disclosure.

### DETAILED DESCRIPTION

Specific structural or functional descriptions disclosed herein are merely illustrative for the purpose of describing embodiments according to the concept of the present disclosure. Embodiments according to the concept of the present disclosure may be implemented in various forms and should not be construed as being limited to the specific embodiments set forth herein.

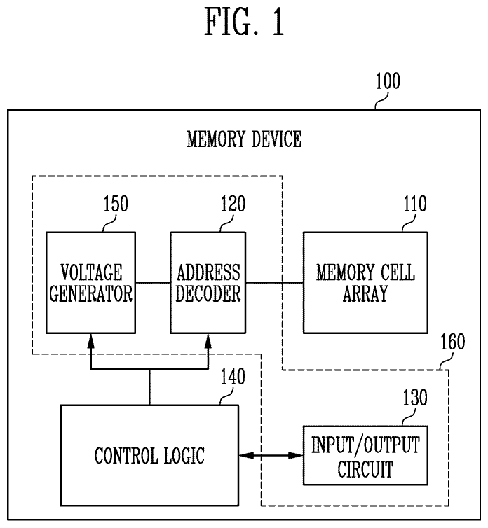

FIG. 1 is a diagram illustrating a memory device 100 according to an embodiment of the present disclosure.

Referring to FIG. 1, the memory device 100 may store data. The memory device 100 may include a memory cell array 110 including memory cells for storing data, an address decoder 120 for decoding a column address, an input and output (input/output) circuit 130 for transmitting and receiving data to and from the memory device 100, a control logic 140, and a voltage generator 150 for generating a plurality of voltages having various voltage levels.

Each of the memory cells included in the memory cell array 110 may be a single-level cell (SLC) that stores one bit of data or a memory cell that stores multi-bit data. A memory cell storing multi-bit data may be a multi-level cell (MLC) storing 2 bits of data, a triple-level cell (TLC) storing 3 bits of data, a quad-level cell (QLC) storing 4 bits of data or a penta-level cell (PLC) storing 5 bits of data depending on the number of bits of the multi-bit data.

The address decoder 120 may be coupled to memory cell array 110 via word lines. The address decoder 120 may decode an address received from the input/output circuit 130 to select a word line. The address decoder 120 may apply a voltage received from the voltage generator 150 to the selected word line. The address decoder 120 may operate in response to a control signal received from control logic 140.

The input/output circuit 130 may include page buffers which read and temporarily store data stored in memory cells. The input/output circuit 130 may output data stored in the page buffers to the outside of the memory device 100, or may store data received from the outside the page buffer and then store the data in the memory cells.

The control logic 140 may control various operations of the memory device 100. The control logic 140 may generate control signals which control the address decoder 120, the input/output circuit 130, and the voltage generator 150 to perform read, program, and erase operations on the memory cell array 110.

The voltage generator 150 may generate voltages necessary for the operation of the memory device 100. The voltage generator 150 may include voltage regulators which generate voltages having various potentials. The voltage generator 150 may generate a program voltage, a verify voltage, and a read voltage required by the memory device 100. The voltages generated by the voltage generator 150 may be supplied to the memory cells included in the memory cell array 110 through the address decoder 120.

In an embodiment of the present disclosure, the address decoder 120, the input/output circuit 130, and the voltage generator 150 may be referred to as a peripheral circuit 160. The control logic 140 may control the peripheral circuit 160 such that operations are performed on the memory cells included in memory cell array 110.

In an embodiment of the present disclosure, the control logic 140 may control the peripheral circuit 160 such that the program operations on the memory cells are performed. The peripheral circuit 160 may perform a program pulse application operation of applying program pulses to the memory cells and a verification operation of detecting whether threshold voltages of the memory cells have reached a target threshold voltage distribution.

The control logic 140 may group the program pulses corresponding to predetermined target threshold voltages into a plurality of groups based on the target threshold voltages of the memory cells. The control logic 140 may control the peripheral circuit 160 such that the program pulses included in a group with a high target threshold voltage are applied to the memory cells earlier than the program pulses included a group with a low target threshold voltage.

The order of the program pulses to be applied to the memory cells may be sorted according to the order of the target threshold voltages. A program inhibit voltage may be applied to the memory cells corresponding to the remaining groups to which the program pulse is not applied when the program pulses are applied. In an embodiment of the present disclosure, the memory cells with the high target threshold voltage may complete a program operation before the memory cells with the low target threshold voltage. The program pulses included in the group with the lower target threshold voltage may be applied to the memory cells later. According to an embodiment of the present disclosure, when the program pulse application operation is performed on the memory cells having the high target threshold voltage, a program disturb caused by the program inhibit voltage being applied to the memory cells having the low target threshold voltage and having already completed the program operation may be minimized.

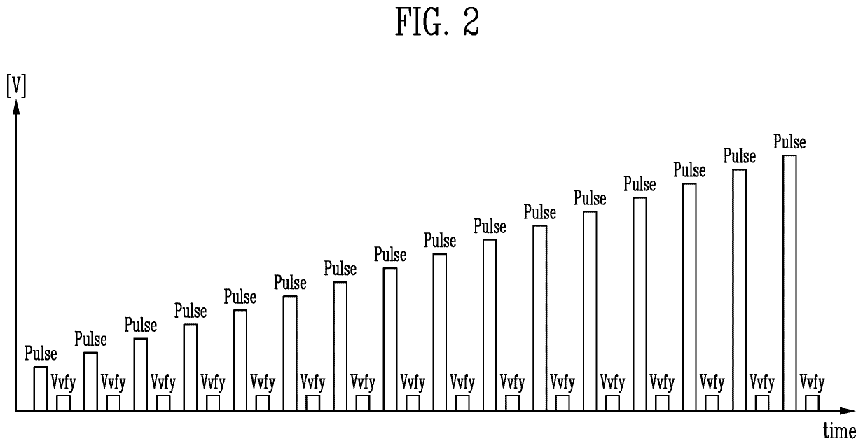

FIG. 2 is a diagram illustrating the program pulses applied to the memory cells during the program operation.

Referring to FIG. 2, the peripheral circuit 160 of FIG. 1 may perform the program operation on the memory cells. The program operation may include a program pulse application operation and a verification operation. The magnitude of the program pulses applied to the memory cells may gradually increase over time. In FIG. 2, the horizontal axis represents time and the vertical axis represents the magnitude of the pulse.

For convenience, in FIG. 2, the number of the program pulses may be 16. A verify voltage Vvfy may be applied to the memory cells after the program pulse is applied to the memory cell. The magnitude of the program pulses may be gradually increased, and the magnitude of the verify voltage Vvfy may be constant.

When the program pulses according to FIG. 2 are applied to the memory cells, the program operation may be completed from the memory cells having the low target threshold voltage. The program inhibit voltage may be applied to the memory cells in which the program operation is completed until the program operation of other memory cells is completed.

Since the boosting level of the memory cell to which the program inhibit voltage is applied is low, a program disturb in which the threshold voltage distribution is widened may occur. When a high program pulse is applied to the memory cells having the high target threshold voltage, and the program inhibit voltage is applied to the memory cells having the low target threshold voltage, a program disturb may occur in the memory cells having the low target threshold voltage. When the magnitude and number of program pulses applied to the memory cell increase, more program disturbances may occur.

As the number of bits stored per memory cell increases, an increase in the number and magnitude of program pulses applied to the memory cell during the program operation is required to improve the threshold voltage distribution of the memory cell. The more memory cells operate with TLC, QLC, and PLC rather than SLC, the more program disturb may occur.

The present disclosure provides a method for minimizing a program disturb that occurs in the program operation.

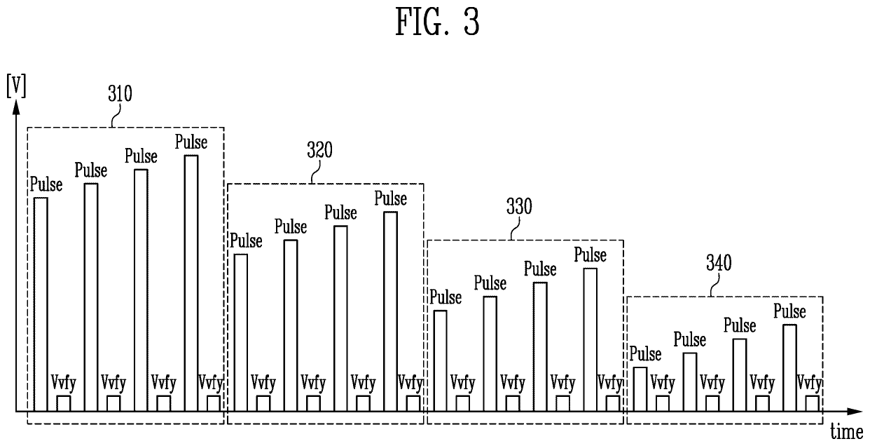

FIG. 3 is a diagram illustrating a program pulse application operation according to an embodiment of the present disclosure.

Referring to FIG. 3, a plurality of program pulses may be grouped, and the program pulses included in each of the plurality of groups may be applied to the memory cells according to the order of the plurality of groups. In FIG. 3, for convenience, the memory cell may be a TLC, and 16 program pulses may be applied to the memory cells during the program operation.

The control logic 140 of FIG. 1 may group a plurality of program pulses to be applied to the memory cells into a plurality of groups according to an order of target threshold voltages of the memory cells. The control logic 140 may group program pulses corresponding to a predetermined number of target threshold voltages in descending order, i.e., from a highest target threshold voltage, to be included in each of the plurality of groups. In another embodiment of the present disclosure, the control logic 140 may group the program pulses corresponding to a predetermined number of target threshold voltages in ascending order, i.e., from a lowest target threshold voltage, to be included in each of the plurality of groups.

In FIG. 3, the control logic 140 may group 16 program pulses into four groups. The control logic 140 may group the program pulses corresponding to the highest threshold voltage and the second highest threshold voltage for TLC, i.e., the seventh threshold voltage and the sixth threshold voltage into a first group 310, group the program pulses corresponding to the fifth threshold voltage and the fourth threshold voltage into a second group 320, group the program pulses corresponding to the third threshold voltage and the second threshold voltage into a third group 330, and group the program pulses correspond to the lowest threshold voltage for TLC, i.e., the first threshold voltage into a fourth group 340. The number of program pulses included in each group may be four. Threshold voltages for TLC may include 7 threshold voltages, which gradually increase from the first threshold voltage to the seventh threshold voltage. The seventh threshold voltage may be the highest threshold voltage for TLC.

In an embodiment of the present disclosure, the control logic 140 may determine a representative threshold voltage of each of the plurality of groups. The control logic 140 may determine, as the representative threshold voltage, the lowest target threshold voltage among the target threshold voltages corresponding to each of the groups. In another embodiment of the present disclosure, the control logic 140 may determine, as the representative threshold voltage, one of the target threshold voltages corresponding to each of the groups. For example, the representative threshold voltage may be the highest threshold voltage or an intermediate value among the target threshold voltages corresponding to the group. The target threshold voltages corresponding to each of the plurality of groups do not overlap with each other, so one of the target threshold voltages corresponding to the group may be the representative threshold voltage.

The control logic 140 may control the peripheral circuit 160 to apply the program pulses corresponding to the representative threshold voltage to the memory cells in descending order, i.e., from the highest representative threshold voltage to the lowest representative threshold voltage. In one embodiment of FIG. 3, the control logic 140 may determine, as the representative threshold voltage, the lowest threshold voltage among the target threshold voltages corresponding to each group. That is, the representative threshold voltage of the first group 310 is the sixth threshold voltage among the sixth and seventh threshold voltages, the representative threshold voltage of the second group 320 is the fourth threshold voltage among the fourth and fifth threshold voltages, the representative threshold voltage of the third group 330 is the second threshold voltage among the second and third threshold voltages, and the representative threshold voltage of the fourth group 340 is the first threshold voltage. The control logic 140 may apply the program pulses in descending order of the representative threshold voltages. That is, the program pulses included in the first group 310 may be applied to the memory cells first, followed by the program pulses included in the second group 320.

The control logic 140 may control the peripheral circuit 160 such that the program pulses included in the first group 310 are applied to the memory cells. When the program pulses included in the first group 310 are applied, the program inhibit voltage is applied to the memory cells corresponding to the program pulses included in the remaining groups, that is, the second group 320, the third group 330, and the fourth group 340.

The control logic 140 may control the peripheral circuit 160 such that the program pulses included in the first group 310 are applied to memory cells first and then the program pulses in the second group 320 are applied to the memory cells. When the program pulses are applied to the second group 320, the program inhibit voltage is applied to the memory cells corresponding to the program pulses included in the remaining groups, that is, the first group 310, the third group 330, and the fourth group 340.

Similarly, the control logic 140 may control the peripheral circuit 160 such that the program pulses included in the third group 330 and the fourth group 340 are sequentially applied to the memory cells after the program pulses in the second group 320 are applied to the memory cells. When the program pulses included in the third group 330 and the fourth group 340 are respectively applied, the program inhibit voltage is applied to the memory cells corresponding to the program pulses included in the remaining groups.

FIG. 3 is only an embodiment of the present disclosure, and thus the number of groups including the program pulses and the number of program pulses included in each group may be different. For example, the number of program pulses included in the first group 310 may be 8, the number of program pulses included in the second group 320 may be 4, and the number of program pulses included in the third group 330 may be 4. Alternatively, the target threshold voltages corresponding to the program pulses included in the first group 310 may be the seventh threshold voltage, the sixth threshold voltage, the fifth threshold voltage, and the fourth threshold voltage, and the target threshold voltages corresponding to the program pulses included in the second group 320 may be the third threshold voltage, the second threshold voltage, and the first threshold voltage.

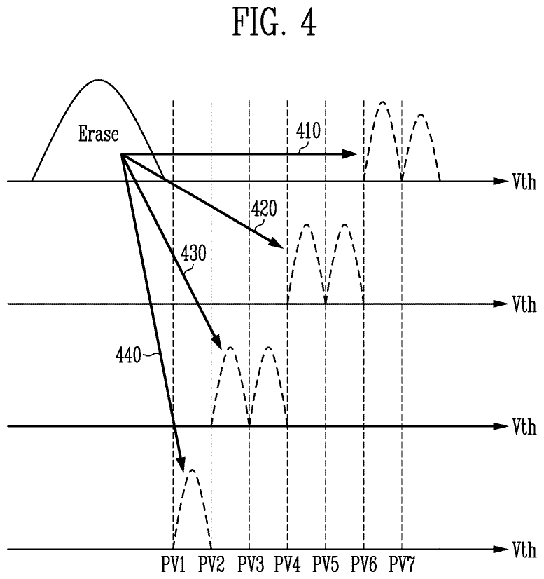

FIG. 4 is a diagram for describing a threshold voltage distribution of the memory cells programmed according to the program pulse application operation of FIG. 3.

Referring to FIG. 4, the threshold voltage distribution of the memory cells is illustrated and changes as the program pulses are applied to the memory cells. FIG. 4 may refer to a change in the threshold voltage distribution of the memory cells when the program pulses of FIG. 3 are applied to the memory cells. Similar to FIG. 3, the memory cell may be a TLC.

Memory cells in an erase state may change the threshold voltages thereof from first to seventh threshold voltage distributions PV1 to PV7 as the program pulses are applied. When the program pulses included in the first group 310 are applied to the memory cells, the threshold voltage distribution of the memory cells may be changed 410 to the sixth threshold voltage distribution PV6 and the seventh threshold voltage distribution PV7. When the program pulses included in the first group 310 are applied, the program inhibit voltage is applied to the memory cells corresponding to the program pulses included in the second group 320, the third group 330, and the fourth group 340, so that the threshold voltage distribution of the remaining memory cells may not be changed.

When the program pulses included in the second group 320 are applied to the memory cells, the threshold voltage distribution of the memory cells may be changed 420 to the fourth threshold voltage distribution PV4 and the fifth threshold voltage distribution PV5. When the program pulses included in the second group 320 are applied, the program inhibit voltage is also applied to the memory cell corresponding to the program pulse included in the first group 310, so that the threshold voltages of the memory cells having the sixth threshold voltage distribution PV6 and the seventh threshold voltage distribution PV7 may also be maintained. Likewise, the program pulses included in the third group 330 are applied to change 430 the threshold voltage distribution of the memory cells to the second threshold voltage distribution PV2 and the third threshold voltage distribution PV3, and the program pulses included in the fourth group 340 may be applied to change 440 the threshold voltage distribution of the memory cells to the first threshold voltage distribution PV1.

Since the program pulses included in the first group 310 to the fourth group 340 are sequentially applied to the memory cells, the threshold voltage distribution of the memory cells is changed in the order of 410, 420, 430, and 440. The memory cells corresponding to the first threshold voltage distribution PV1, the second threshold voltage distribution PV2, and the third threshold voltage distribution PV3 are programmed later than the memory cells corresponding to the fourth threshold voltage distribution PV4 to the seventh threshold voltage distribution PV7. Since a program disturb occurs in the memory cells having the lower target threshold voltage than in the memory cells having the higher target threshold voltage, the program disturb may be minimized when the memory cells having the relatively lower target threshold voltage are programmed later than the memory cells having the higher target threshold voltage.

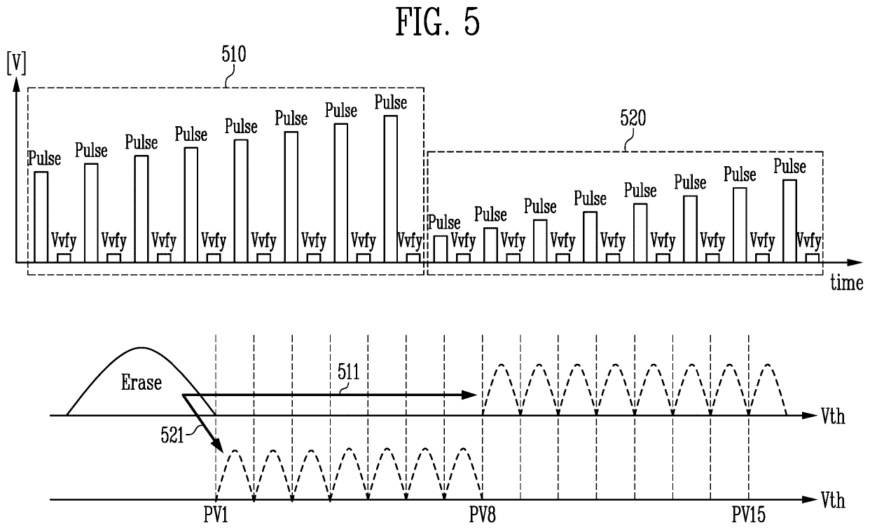

FIG. 5 is a diagram illustrating the program pulse application operation and the threshold voltage distribution of the memory cells according to another embodiment of the present disclosure.

Referring to FIG. 5, the program pulses applied to the memory cells and a change in the threshold voltage distribution of the memory cells with the application of the program pulses may be shown. For convenience, in FIG. 5, the memory cell may be a QLC, the number of program pulse groups is 2, and the number of the program pulses may be 16.

The control logic 140 of FIG. 1 may group, into a first group 510, the program pulses corresponding to the 8 target threshold voltages in the descending order, i.e., from the highest target threshold voltages among the target threshold voltages of the memory cells, and may group the remaining target threshold voltages into a second group 520. The number of program pulses included in the first group 510 and the second group 520 may be the same as 8, respectively. The number of target threshold voltages corresponding to the program pulses included in the first group 510 is 8, and the number of target threshold voltages corresponding to the program pulses included in the second group 520 is 7.

The program pulses included in the first group 510 may be applied to the memory cells earlier than the program pulses included in the second group 520. The threshold voltage of the memory cells in the erase state is changed 511 from eighth to the fifteenth threshold voltage distributions PV8 to PV15 in response to the program pulses included in the first group 510 being applied. The program inhibit voltage may be applied to the memory cells corresponding to the program pulses included in the second group 520 when the program pulses included in the first group 510 are applied.

After the program pulses included in the first group 510 are applied, the program pulses included in the second group 520 may be applied to the memory cells. The program inhibit voltage may be applied to the memory cells corresponding to the program pulses included in the first group 510 when the program pulses included in the second group 520 are applied. The threshold voltages of the memory cells corresponding to the program pulses included in the first group 510 may not be changed, and the threshold voltages of the memory cells corresponding to the program pulses included in the second group 520 may be changed 512 from the first to seventh threshold voltage distributions PV1 to PV7.

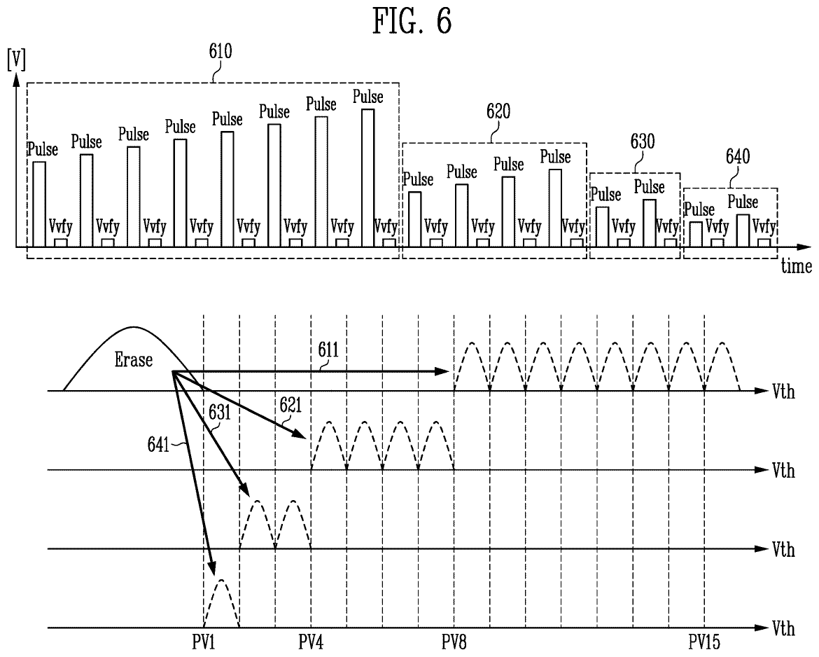

FIG. 6 is a diagram illustrating the program pulse application operation and the threshold voltage distribution of the memory cells according to another embodiment of the present disclosure.

Referring to FIG. 6, the program pulses applied to the memory cells and the change in the threshold voltage distribution of the memory cells with the application of the program pulses may be shown. For convenience, in FIG. 6, the memory cell may be a QLC, the number of program pulse groups is 4, and the number of the program pulses may be 16. In FIG. 6, descriptions that overlap with those in FIG. 5 may be omitted.

The control logic 140 of FIG. 1 may group, into a first group 610, the program pulses corresponding to the 8 target threshold voltages in descending order among the target threshold voltages of the memory cells, may group, into a second group 620, the program pulses not included in the first group 610 and corresponding to 4 target threshold voltages in the descending order of the target threshold voltages, may group, into a third group 630, the program pulses not included in the first group 610 and the second group 620 and corresponding to 2 target threshold voltages in the descending order of the high target threshold voltages, and group the remaining program pulses into a fourth group 640.

The program pulses included in the first group 610 may correspond to the eighth to fifteenth threshold voltage distributions PV8 to PV15, and the first group 610 may include 8 program pulses. The program pulses included in the second group 620 may correspond to the fourth to seventh threshold voltage distributions PV4 to PV7, and the second group 620 may include 4 program pulses. The program pulses included in the third group 630 may correspond to the second threshold voltage distribution PV2 and the third threshold voltage distribution PV3, and the third group 630 may include 2 program pulses. The program pulses included in the fourth group 640 may correspond to the first threshold voltage distribution PV1, and the fourth group 640 may include 2 program pulses.

The program pulses included in the first group 610 may be applied to the memory cells earlier than the program pulses included in the second group 620. The threshold voltage of the memory cells in the erase state is changed 611 from the eighth threshold voltage distribution PV8 to the fifteenth threshold voltage distribution PV15 in response to the program pulses included in the first group 610 being applied. The program inhibit voltage may be applied to the memory cells corresponding to the program pulses included in the second group 620, the third group 630, and the fourth group 640 when the program pulses included in the first group 610 are applied.

Since the program pulses included in the first group 610 to the fourth group 640 are sequentially applied, the threshold voltage distribution of the memory cells is changed in the order of 611, 621, 631, and 641. The memory cells corresponding to the first threshold voltage distribution PV1, the second threshold voltage distribution PV2, and the third threshold voltage distribution PV3 are programmed later than the memory cells corresponding to the fourth threshold voltage distribution PV4 to the fifteenth threshold voltage distribution PV15.

In an embodiment of the present disclosure, the number of target threshold voltages corresponding to the program pulses included in the first group 610 may be greater than or equal to the number of target threshold voltages corresponding to the program pulses included in the second group 620. That is, the number of target threshold voltages corresponding to the program pulses included in the group that are later applied to the memory cells may be less than or equal to the number of the target threshold voltages that correspond to program pulses that are first applied to the memory cell. The control logic 140 may group the number of target threshold voltages corresponding to the program pulses included in each of the second group 620, the third group 630, and the fourth group 640 less than or equal to the number of target threshold voltages corresponding to the program pulses included in the first group 610.

Since FIGS. 5 and 6 are merely embodiments, the number of groups including the program pulses and the number of program pulses included in each group may vary. For example, the number of program pulses included in each group may be the same or the number of target threshold voltages corresponding to the program pulses included in each group may be same.

FIGS. 3 to 6 illustrate the case where the memory cell is a TLC or QLC, but when the memory cell is PLC or higher, the control logic 140 may control the peripheral circuit 160 to group the program pulses and first apply the program pulses included in the group with the high target threshold voltage to the memory cell. The program pulses included in the group with the low target threshold voltage may be applied later to minimize program disturb which occurs in memory cells having the low target threshold voltage.

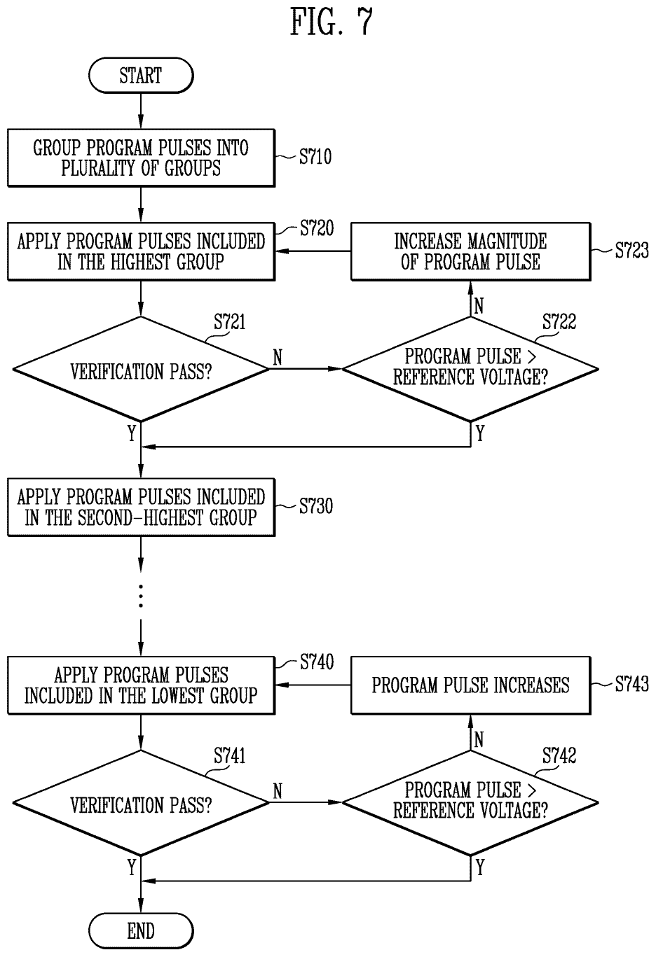

FIG. 7 is a flowchart illustrating the program operation according to an embodiment of the present disclosure. The program operation of FIG. 7 may be performed by the memory device 100 of FIG. 1.

Referring to FIG. 7, the memory device 100 may apply the program pulses to the memory cells to perform the program operation. The memory device 100 may group the program pulses according to an order of the target threshold voltages, and first apply, to the memory cells, the program pulses included in the group having the highest target threshold voltage. The application order of the program pulses to be applied to the memory cells may be sorted to minimize program disturb which occurs in the memory cells having the relatively low target threshold voltage.

At S710, a control logic (e.g., the control logic 140 of FIG. 1) may group the program pulses to be applied to the memory cells connected to a selected word line into the plurality of groups according to the order of the target threshold voltages of the memory cells. For each of the plurality of groups, the control logic may group the program pulses corresponding to the predetermined number of target threshold voltages in descending order (i.e., from the highest target threshold voltage to the lowest target threshold voltage) among the target threshold voltages of the memory cells.

In an embodiment of the present disclosure, the control logic may group the program pulses corresponding to m target threshold voltages into a first group in descending order, and group the program pulses corresponding to n target threshold voltages in descending order among the target threshold voltages of the remaining memory cells into a second group, where m and n are natural numbers and m may be greater than or equal to n.

The control logic may determine a representative threshold voltage for each of the plurality of groups. The control logic may determine, as the representative threshold voltage of each of the plurality of groups, the lowest target threshold voltage of the target threshold voltages of the memory cells corresponding to the program pulses included in each of the plurality of groups.

At S720, the control logic may apply, to the memory cells, the program pulses included in the highest group having the highest representative threshold voltage among the plurality of groups. The program pulses applied to the memory cells may be determined based on the representative threshold voltage. When the program pulses included in the highest group are applied, the control logic may apply the program inhibit voltage to the remaining memory cells except for the memory cells corresponding to the program pulses included in the highest group.

At S721, the control logic may perform the verification operation on the memory cells to which the program pulses included in the highest group are applied. When the result of the verification operation is a verification pass, S730 is performed. When the result of the verification operation is a validation fail, S722 is performed.

At S722, the control logic may compare the magnitude of the program pulse applied to the memory cells with the magnitude of a reference voltage determined based on the representative threshold voltage. When the magnitude of the program pulse applied to the memory cells is less than or equal to the magnitude of the reference voltage, the control logic may increase the magnitude of the program voltage by one step (S723). After S723, at S720, an increased program pulse may be applied back to the memory cells. The operation of increasing the magnitude of the program pulse according to the verification result may correspond to an incremental step pulse program (ISPP) operation. The control logic may end the program pulse application operation on the memory cells corresponding to the highest group when the magnitude of the program pulse applied to the memory cells is greater than the magnitude of the reference voltage. Subsequently, S730 may be performed.

At S730, the control logic may apply, to the memory cells, the program pulses included in the second-highest group among the plurality of groups based on the representative threshold voltage. The operation of applying the program pulse to the memory cells may correspond to the description of S720 to S723.

The control logic may control the peripheral circuit to apply the program pulses included in each of the plurality of groups to the memory cells sequentially in the descending order of the representative threshold voltage.

At S740, the control logic may apply, to the memory cells, the program pulses included in the lowest group with the lowest representative threshold voltage among the plurality of groups. At S741, the control logic may perform the verification operation on the memory cells corresponding to the applied program pulse. When the result of the verification operation is a verification pass, the program operation may be terminated. When the result of the verification operation is a verification fail, S742 may be performed. At S742, the control logic may compare the magnitude of the program pulse to which the memory cells are applied with the magnitude of the reference voltage. When the magnitude of the program pulse is greater than the magnitude of the reference voltage, the program operation may be terminated. When the magnitude of the program pulse is less than or equal to the magnitude of the reference voltage, S743 may be performed. At S743, the control logic may increase the magnitude of the program pulse by a predetermined size. After S743, S740 of applying the increased program pulse to the memory cells may then be performed again. The operation of applying the program pulse to the memory cells may correspond to the description of S720 to S723.

The description of each operation in FIG. 7 may correspond to the description of FIGS. 1 to 6.

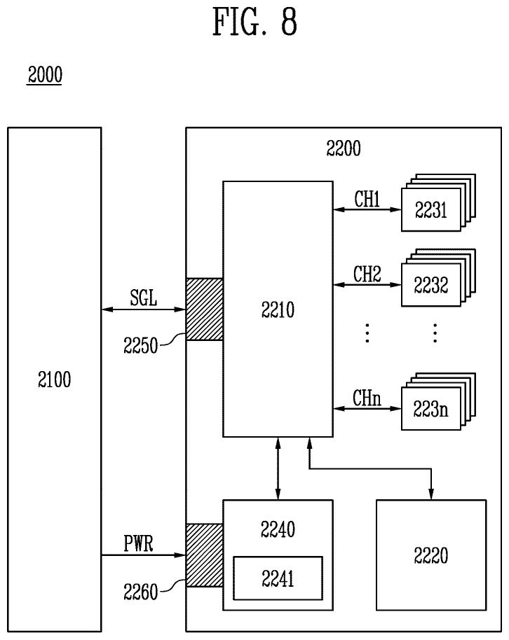

FIG. 8 is a diagram illustrating a data storage system 2000 including a memory system according to an embodiment of the present disclosure.

Referring to FIG. 8, the data storage system 2000 may include a host device 2100 and an SSD 2200.

The SSD 2200 may include a controller 2210, a buffer memory device 2220, non-volatile memories 2231-223n, a power supply 2240, a signal connector 2250, and a power connector 2260. The SSD 2200 may include the memory device 100 described in FIGS. 1 to 7.

The buffer memory device 2220 may temporarily store data to be stored in the non-volatile memories 2231 to 223n. In addition, the buffer memory device 2220 may temporarily store data read from the non-volatile memories 2231 to 223n. The data temporarily stored in the buffer memory device 2220 may be transmitted to the host device 2100 or the non-volatile memories 2231 to 223n under the control of the controller 2210.

The non-volatile memories 2231 to 223n may be used as a storage medium of the SSD 2200. Each of the non-volatile memories 2231 to 223n may be coupled to the controller 2210 through a plurality of channels CH1 to CHn. One or more non-volatile memories may be coupled to one channel. The non-volatile memories connected to one channel may be connected to the same signal bus and data bus.

The controller 2210 may control various operations of the SSD 2200. In an embodiment of the present disclosure, the controller 2210 may control the SSD 2200 so that the program operation is performed. The controller 2210 may group the program pulses applied to the memory cells to be programmed into the plurality of groups, and control the SSD 2200 to apply the program pulses included in the plurality of groups to the memory cells in the descending order of the target threshold voltages. Accordingly, the threshold voltage distribution of the non-volatile memories 2231 to 223n may be improved.

The power supply 2240 may provide a power PWR input through the power connector 2260 to the inside of the SSD 2200. The power supply 2240 may include an auxiliary power supply 2241. The auxiliary power supply 2241 may supply power so that the SSD 2200 may be normally terminated when a sudden power off occurs. The auxiliary power supply 2241 may include large capacity capacitors capable of charging power PWR.

The controller 2210 may exchange signals SGL with the host device 2100 through the signal connector 2250. The signal SGL may include a command, an address, data, or the like. The signal connector 2250 may be composed of various types of connectors depending on the interface between the host device 2100 and the SSD 2200.

The present invention is defined by the following claims rather than by the foregoing detailed description, and all modifications and variations derived from the meaning and scope of the claims and their equivalents are to be construed as included in the present invention.

According to embodiments of the present disclosure, a memory device and a program operation method for improving the performance of the program operation are provided. The memory device may reduce a program disturbance in which a threshold voltage distribution of memory cells having a low target threshold voltage is widened, by grouping program pulses to be applied to memory cells according to an order of a target threshold voltage and applying a program pulse corresponding to a group having a high target threshold voltage earlier than a program pulse corresponding a group having a low target threshold voltage. Furthermore, the embodiments may be combined to form additional embodiments.

What is claimed is:

1. A memory device comprising:
a memory cell array including a plurality of memory cells coupled to a selected word line;
a peripheral circuit for performing a program operation on the plurality of memory cells by applying program voltages to the selected word line; and
a control logic for grouping a plurality of program pulses to be applied to the plurality of memory cells into a plurality of groups according to an order of target threshold voltages of the plurality of memory cells, and controlling the peripheral circuit so that the program pulses included in the plurality of groups are applied to the plurality of memory cells in descending order of representative threshold voltages of the plurality of groups,
wherein a representative threshold voltage of each of the plurality of groups is the lowest target threshold voltage among the target threshold voltages of the program pulses included in each of the plurality of groups.

2. The memory device of claim 1, wherein the control logic groups program pulses corresponding to m target threshold voltages in descending order of target threshold voltages of the plurality of memory cells into a first group, and groups program pulses corresponding to n target threshold voltages into a second group in descending order of the remaining target threshold voltages, and
wherein m is greater than or equal to n.

3. The memory device of claim 2, wherein the control logic controls the peripheral circuit such that the program pulses included in the first group are applied to the plurality of memory cells before the second group.

4. The memory device of claim 3, wherein, when the program pulses included in the first group are applied, the control logic controls the peripheral circuit to apply a program inhibit voltage to remaining memory cells of the plurality of memory cells except for memory cells corresponding to the program pulses included in the first group.

5. The memory device of claim 3, wherein, after completing an operation of applying the program pulses included in the first group, the control logic controls the peripheral circuit to apply the program pulses included in the second group to the plurality of memory cells.

6. The memory device of claim 5, wherein, when the program pulses included in the second group are applied, the control logic controls the peripheral circuit to apply a program inhibit voltage to remaining memory cells of the plurality of memory cells except for memory cells corresponding to the program pulses included in the second group.

7. The memory device of claim 1, wherein the control logic groups program pulses corresponding to a predetermined number of target threshold voltages in ascending order of target threshold voltages of the plurality of memory cells included in each of the plurality of groups.

8. The memory device of claim 7, wherein the control logic controls the program pulses included in the plurality of groups to apply the plurality of memory cells sequentially in descending order of the representative threshold voltages.

9. The memory device of claim 8, wherein the control logic controls the peripheral circuit to apply a program inhibit voltage to remaining memory cells of the plurality of memory cells except for memory cells corresponding to an applied program pulse.

10. The memory device of claim 9, wherein the program pulse is determined based on the representative threshold voltage of a group associated with the program pulse, and
wherein the control logic increases a magnitude of the program pulse in response to a verification failure for the memory cells to which the program pulse is applied.

11. The memory device of claim 10, wherein the control logic is configured to complete a program pulse application operation on the memory cells to which the program pulse is applied in response to a magnitude of the program pulse exceeding a magnitude of a reference voltage determined based on the representative threshold voltage.

12. A method of manufacturing a memory device, the method comprising:
grouping a plurality of program pulses to be applied to a plurality of memory cells coupled to a selected word line into a plurality of groups according to an order of target threshold voltages of the plurality of memory cells;
determining a representative threshold voltage of each of the plurality of groups to be a lowest target threshold voltage of the target threshold voltages of the plurality of memory cells corresponding to program pulses included in each of the plurality of memory cells; and
applying program pulses corresponding to the representative threshold voltage included in each of the plurality of groups sequentially according to descending order of the representative threshold voltages of the plurality of groups.

13. The method of claim 12, wherein grouping the plurality of program pulses includes grouping the program pulses corresponding to a predetermined number of target threshold voltages in descending order of the target threshold voltages of the plurality of memory cells into the plurality of groups, respectively.

14. The method of claim 13, wherein grouping the plurality of program pulses comprises:
grouping program pulses corresponding to m target threshold voltages into a first group in descending order of the plurality of memory cells; and
grouping program pulses corresponding to n target threshold voltages into a second group in descending order of target threshold voltages of remaining memory cells, and
wherein m is greater than or equal to n.

15. The method of claim 12, wherein the grouping the plurality of program pulses includes grouping program pulses corresponding to a predetermined number of target threshold voltages in ascending order of the target threshold voltages of the plurality of memory cells into each of the plurality of groups.

16. The method of claim 15, wherein the number of target threshold voltages corresponding to the group to which the included program pulses are applied is less than or equal to a number of target threshold voltages corresponding to a group in which an application operation of included program pulses has ended.

17. The method of claim 12, wherein, when the program pulses are applied to each of the plurality of groups, applying the program pulses includes applying a program inhibit voltage to remaining memory cells of the plurality of memory cells except for memory cells corresponding to the program pulses included in the group to which the program pulse is applied.

18. The method of claim 12, wherein applying the program pulses comprises:
applying a program pulse determined based on the representative threshold voltage among the program pulses included in each of the plurality of groups;
increasing a magnitude of the program pulse in response to a verification result for memory cells to which the program pulse is applied being a failure; and
terminating a program pulse application operation on the memory cells to which the program pulse is applied in response to the magnitude of the program pulse exceeding a magnitude of a reference voltage determined based on the representative threshold voltage.

19. The method of claim 14, wherein applying the program pulses comprises:
applying, to the plurality of memory cells, a program pulse corresponding to the representative threshold voltage among the program pulses included in the first group;
applying a program inhibit voltage to remaining memory cells of the plurality of memory cells except for the memory cells corresponding to the program pulses included in the first group when the program pulses in the first group are applied;
applying the program pulses included in the second group to the plurality of memory cells after the program pulse application operation for the first group is completed; and
applying the program inhibit voltage to remaining memory cells of the plurality of memory cells except for the memory cells corresponding to the program pulses included in the second group while the program pulses in the second group are applied.
